(19) United States
(12) Patent Application Publication
(10) Pub. No.: US 2018/0175639 A1
(43) Pub. Date: Jun. 21, 2018

(54) ELECTRICAL EQUIPMENT AND ELECTRONIC CIRCUIT FOR ANTI CORROSION TREATMENT ON METAL SURFACES

(71) Applicants: JEFFERSON CARLOS TASCA, Indaiatuba-SP (BR); SERGIO RODRIGUES TORRES, Indaiatuba-SP (BR); CLEBER JEAN ARAUJO LOPES, Jardim Santo Andre - SP (BR)

(72) Inventors: JEFFERSON CARLOS TASCA, Indaiatuba-SP (BR); SERGIO RODRIGUES TORRES, Indaiatuba-SP (BR); CLEBER JEAN ARAUJO LOPES, Jardim Santo Andre - SP (BR)

(21) Appl. No.: 15/381,308

(22) Filed: Dec. 16, 2016

(51) Int. Cl. H02J 7/00; H05K 5/03; H02M 3/08; H02M 1/44

(52) U.S. Cl. CPC H02J 7/0021; H02M 1/44; H02M 3/08; H05K 5/03

(57) ABSTRACT

Developed to work in two energized circuit configurations (C1) from alternating current and energized circuit (C2) from direct current, both mounted in their boxes, respectively box (1) and box (2) to treat metal surface against corrosion. Through the circuit (C1), the box (1) works where only there is power originated from the electrical grid, alternating with voltage from 95 to 250 V, for anti-corrosion treatment for appliances, gates, railings, solar heating devices, air conditioning and others, in industrial environments for all types of machinery and structures, as well as for large equipment such as civil construction, bridges, containers, ships, oil platforms, wind towers, transmission of phone signals, electricity, etc. Through the circuit (C2), the box (2) works from the direct current originated from batteries, whatever these are, with a voltage between 9 and 30 V, for treatment in light automobiles, bodywork, radiator, engine block, wheel brake, exhaust and other points. In heavy automotive, they can be used in the treatment of trucks, buses, heavy and agricultural machinery, power generators, high-performance equipment, and vehicles of electrical charges between 12 and 24 V, and when connected to the motorcycle battery, for treatment of the entire metal frame, wheels, chains, exhaust, etc.

This descriptive report refers to an application for a patent for an electronic device developed for anti-corrosion treatment of metal surfaces, which presents as a novelty an electronic circuit whose arrangement allows it to be, through an alternating current circuit, energized on voltage of 95 and 250V, and in the case of direct current, through another circuit, powered by battery on variable voltage from 9 to 30V. Thus, the anti-corrosion equipment has expanded its ability to power up, adapting to market reality and also to different situations and places where it is used to treat structures and any metal surfaces/roofs, whether light and heavy vehicles, agricultural machines, boats, appliances, pipes, tanks, telecommunication towers, in short, all kinds of surfaces exposed to harsh environments or not, in various operating segments known by the society.

### STATE OF THE ART

As it is well known by the professionals from all areas where metallic materials are used in general, their surfaces are subject to electrochemical reaction with the elements of the media where they are employed, resulting in the process of corrosion and their degradation. Being ore, the metal is in the chemical form of lower energy in relation to their media. The steelmaking process purifies the metal and leaves it in a high-energy and chemically unstable condition, however, since everything in nature tends to return to the lower energy level, steps should be taken so that, in this case, unwanted corrosions are avoided and thus slow this natural process of seeking material for energy balance.

The metals in the automotive industry, for example, are subject to corrosion from the painting risks caused by scratches or slight impacts, whereby moisture resulted from rain, mud, sea atmosphere and other natural elements penetrate. Not only in the automotive industry, the losses caused by corrosion incur in more use of energy and labor, impacting production (for maintenance and cathodic protection processes, covering paintings and others), also requiring downtime for replacements. In the oil industry, especially by the highly aggressive/abrasive temperature and pressure environment, the entire production chain is adversely affected by corrosive agents which attack equipment degrading them quickly, favoring oil/gas escape through fractures at critical points of the pipes, which translates in large financial losses, contamination and, depending on the work environment, even bringing risks to human life. It is estimated that 20% of the steel produced in the world is intended for replacement of corroded equipment or equipment part or the entire material with metallic property.

One can imagine the problem of corrosive attack, for example, on metallic towers that support antennas for telecommunication, radio communication, wireless systems and other networks, the structures of which are almost mandatorily made of metal for greater mechanical strength and that, just for being outdoor they end up suffering corrosion in many places, affecting their operation. In addition, due to the height and greatness of such structures, the access for anti-corrosion treatment becomes cornered. Mills in general spend huge amounts to combat corrosion, which occurs with more intensity by the use of various acidic substances from industry and, especially, in rainy periods, deteriorating metal parts, pipes, storage tanks and attacking almost all equipment with metallic properties. Water, sewage and effluent treatment stations also suffer from corrosion, and the useful life of their equipment having dramatically decreased from pipes to flanges, pumps, dosers, stopcocks, valves, pliable materials, gaskets, in short, all sorts of devices are, in fact, subject to such deterioration occurred from excess moisture.

Therefore, in order to inhibit the corrosion problem, the metal damaged points receive the incidence of electrons so that the existing atoms in the corrosive substances are affected by these loads, becoming neutral and forming thin, adherent, compact, nonporous rust layer which insulates the metal surface substantially, almost halting the corrosion process. In already corroded metals, after treatment, the existing rust is gradually being replaced by protective layer so that, in this way, the surface remains with new look and has its service life expanded.

In this sense specific electronic devices have been developed for such purpose. As an example, it may be cited, by way of illustration, the equipment of document BR 10 2014012793 3 called “ANTI-CORROSION ELECTRONIC EQUIPMENT FOR METAL SETS”, deposited by the applicant himself/herself of the new application to be detailed later. As explained in said document BR 102014012793 3, the anti-corrosive techniques are based briefly on the destruction of at least one of electrochemical cell elements, being such techniques: a) Electrical insulation—interlayer, applied between two metals or alloys, forming an insulator which aims to eliminate the electrical continuity between the metal parts in order to prevent passage of electrons between the anodic and cathodic areas; b) Coatings—applied on the metal surface aiming at avoiding contact with the electrolyte. The coating in addition to protecting the metal surface by barrier, it can also provide anodic protection, as is the case of the less noble metal coatings which act as galvanic anode; c) Painting—protection by barrier, being widely used in air metal structures and requires constant maintenance. Some paints include additives in its composition that confer the property of acting as galvanic anode; d) Metallic coatings—act in anti-corrosion protection through two distinct mechanisms: by barrier and as galvanic anode. In the barrier protection, the structure to be protected is coated with a more cathodic metal film, or yet by a metal undergoing passivation. In the case of galvanic anode protection, the structure is coated with a more anodic metal film; e) Protective oxides—the oxides forming over the metal surface are used due to the media action, in order to obtain the anti-corrosive protection by barrier. The most common are anodizing, chromatizing and phosphating; f) Cathodic protection—consists of modifying the electrical potential of the structure that initially undergoes corrosion, making it the cathode of a cell, where the anode is another external structure where corrosive processes can be monitored. The cathodic protection does not eliminate corrosion but transfers it to an external structure which, when necessary, can be replaced. Cathodic protection can be carried out by galvanic anode or by impressed current depending on the conductivity of the media where the structure to be protected operates. In very conductive medias, it is possible to use galvanic anodes, while in low conductivity medias, only impressed current protection is feasible.

Anyway, an equipment powered by alternating current in 110 or 220V voltage via electric power grid or by direct current via 12V voltage battery is demanded in the aforementioned application BR 10 2014 012793 3, when an electric load incurs on the metal surface to bombard electrons and inhibit the corrosion process. Despite its effectiveness in relation to anti-corrosion treatment, this equipment protected by BR 10 2014 012793 3 has the only problem, also detected by the inventor himself, of not offering the versatility to work through direct current battery feeding in 9 or 24V voltage, commonly found in the market. These direct current batteries in 9 or 24V voltage, as known, are widely used especially in the automotive industry.

Thus, for the current anti-corrosion treatment, the professional is required to purchase specific anti-corrosion equipment for each optional voltage—in the case for direct current in 9 or 24V voltage. In the case of alternating current, the user is restricted to 110 or 220V voltage, and any variation in power originated from the grid requires the use of a transformer (which should be available to the professional) otherwise it may cause malfunction or even equipment shutdown. Moreover, this lack of option can be felt when anti-corrosive treatment in places of difficult access, where, for some reason, the power supplies are not compatible with the voltage required by the equipment, for its perfect operation.

### Objective of the Invention

In order to solve the above problem, the author of application BR 102014012793 3 and of the application now reason of patent, improved his/her electronic equipment through the development of two circuits electronic circuits that can be powered (energized) by alternating current, with voltage from 95 to 250V or powered (energized) by direct current through the use of batteries with voltage from 9 to 30V. Thus, the equipment for anti-corrosion treatment satisfies multiple voltages in different situations and places of use.

Explained superficially, the improvement is further detailed through the drawings as follows:

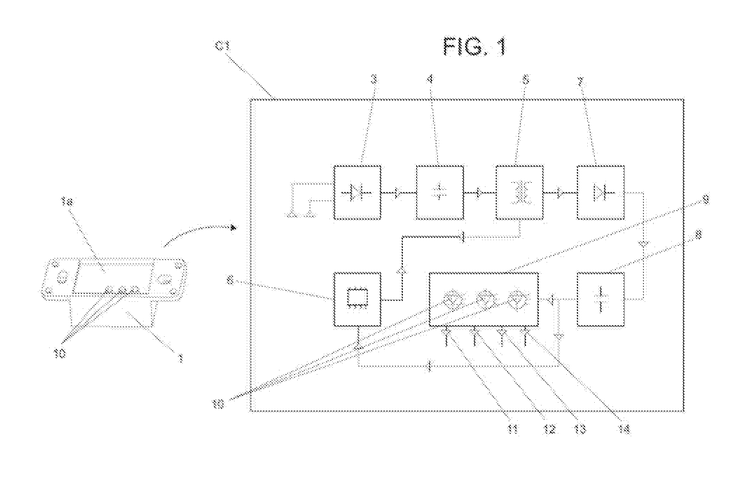

FIG. 1—shows the equipment in box format and, on the scheme on the side, the diagram of its electronic circuit for a power from an alternating current supply (electrical grid) with 95 to 250V voltage;

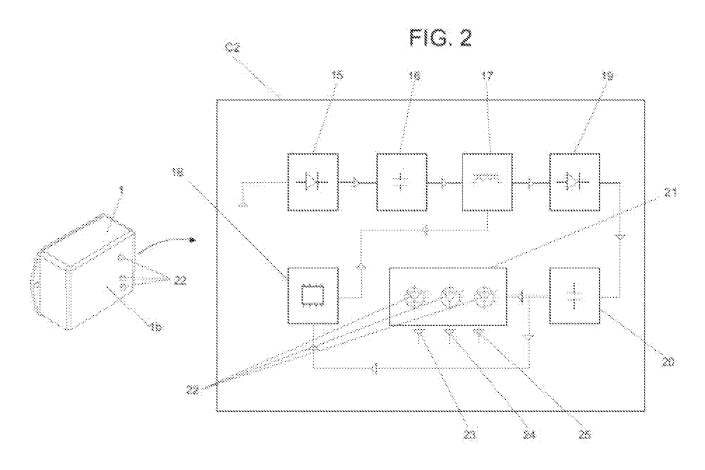

FIG. 2—shows the equipment in box format and, on the scheme on the side, the diagram of the electronic circuit for a power from a direct current supply (battery) with voltage from 9 to 30V.

In compliance with the attached drawings, the “EQUIPMENT ELECTRO-ELECTRONIC CIRCUIT IMPROVEMENT FOR ANTI-CORROSION TREATMENT ON METAL SURFACES”, consists of equipment for anti-corrosion treatment system on metal surfaces, under box construction, being one box (1) with cover (1a) mounted with circuit (C1) for alternating current with voltage from 95 to 250V and one box (2) with cover (2a) mounted with circuit (C2) for direct current with voltage from 9 to 30V.

In the configuration of the box (1) for alternating current, its circuit (C1) receives, always connected in series and by wiring, the electro-electronic components being a current rectifier (3), an interference reducing filter (4), a switching and isolation transformer (5) that is communicant with an integrated control circuit (6) and also connected to a secondary rectifier (7), besides a secondary filter (8) communicant with the integrated control circuit (6) and also connected to a current controller (9) with three charge indicator LED-type lamps (10) having four outputs, being output 1 (11), output 2 (12), common output (13) and output to ground wire (14).

In the configuration of the box (2) for direct current, its circuit (C2) receives, always connected in series and by wiring, an over-current protector and polarity inverter (15), an interference reducing filter (16) connected to a high-frequency inductor (17) that is communicant with an integrated control circuit (18) and also connected to a current rectifier (19), besides a secondary filter (20) equally communicant with the integrated control circuit (18) and also connected to a current controller and charge indicator (21). This component (21) consists of three charge indicator LED-type lamps (22), having three outputs being output 1 (23), output 2 (24), and common output (25).

In both configurations, boxes (1) and (2), all electrical and electronic circuits are encapsulated and receive a protective layer of epoxy resin.

Thus, in the case of work where there is only power from the electrical grid, the box (1) will work through the circuit (C1) which must be grounded through the output to ground wire (14) then being connected to that of the electrical grid and to the metal surface to be treated. In this configuration, the box (1) is especially useful in homes (110/220V), for treatment in appliance surfaces such as refrigerators, freezers, stoves, washing machines, etc., gates, railings, solar heating devices, air conditioning and others. It can be used in industrial environments (110/220V) to all kinds of machinery such as boilers, lathes, rolling mills, pipelines, pipes, tools of any kind and devices with metallic properties. The same applies to large equipment/projects (including solar powered), as structure of civil constructions, bridges, containers, ships, oil platforms, wind towers, transmission of phone signals, electricity, etc. Being so ready for use through the rectifier (3) of the circuit (C1), the alternating current is converted into low voltage direct current, having reduced magnetic interferences through the reducing filter (4). Then, the switching and isolation transformer (5), working with the integrated control circuit (6) converts high voltage direct current (150˜350V) into high frequency alternating current (200 hz) and low voltage (near 2V), with pulse width control and over-current protection, over voltage, under current, under voltage and voltage stabilization and electron flow in the output. It also makes the isolation of the electrical grid with the output (14). In the next stage, rectifying by the secondary rectifier (7) is performed and then the high frequency filtering by the secondary filter (8). Finally, the output current flow control is indicated in the circuit (9), the LEDs (10), being one for each output (11) and (12) and (13), which when lit indicate warning signal, i.e. they warn that the respective output is not connected or energized and that the equipment is not working properly.

In the case of work where there is no power supply from the electrical grid available, the box (2) can be used from direct current originated from batteries, whatever these are, with voltage between 9 and 30V, when, by its circuit (C2) should be connected to the battery and to the metal surface to be treated. Under these conditions, the box (2) connected to the vehicle battery, acts for the treatment of light automotive structure, bodywork, radiator, engine block, braking wheels, exhaust and other points.

In heavy automotive, it can be used in the treatment of trucks, buses, heavy and agricultural machines, power generators, high-performance equipment, and vehicles of electrical charges between 12 and 24V, and when connected to the motorcycle battery, for treatment of all the metal frame, wheels, chains, exhaust, etc. After being powered from the battery, the incoming current in the circuit (C2) of the box (2) suffers action of the over-current protector and polarity inverter (15), going through the interference reducing filter (16). Then the current goes through the high-frequency inductor (17) working with the integrated switching control circuit (18) which converts the battery voltage from 9 to 30 Vdc into high-frequency alternating current, 200 Khz and low voltage, near 2V. In the next stage, the current goes through the rectifier (19) and high-frequency filtering by means of the secondary filter (20) that is also connected to the integrated switching circuit (18) for reducing magnetic interference emission. Finally, the current is passed by the current control circuit and charge indicator (21), whose LEDs (22) when lit indicate by the outputs (23), (24) and (25), warning signal, i.e. they warn which respective output is not connected or energized and whether the equipment is working properly. The application of epoxy resin (encapsulation) on the circuits ensures that they are shielded against adverse weather conditions and also makes them waterproof.

1—IMPROVEMENT IN ELECTRICAL EQUIPMENT AND ELECTRONIC CIRCUIT FOR ANTI-CORROSION TREATMENT ON METAL SURFACES made from a box (1) with cover (la) mounted with circuit (C1) for alternating current in voltage from 95 to 250V, said circuit (C1) consists of electrical and electronic components always connected in series and by wiring, characterized by a current rectifier (3), an interference reducing filter (4), a switching and isolation transformer (5) which is communicant with an integrated control circuit (6) and also connected to a secondary rectifier (7), besides a secondary filter (8) equally communicant with the integrated control circuit (6) and also connected to a current controller (9) with three charge indicator LED-type lamps (10), having four outputs, with output 1 (11), output 2 (12), common output (13) and output to ground wire (14).

2—IMPROVEMENT IN ELECTRICAL EQUIPMENT AND ELECTRONIC CIRCUIT FOR ANTI-CORROSION TREATMENT ON METAL SURFACES, according to claim 1, made from one box (2) with cover (2a) mounted with circuit (C2) for direct current in voltage from 9 to 30V, said circuit (C2) consists of electrical and electronic components always connected in series and by wiring, characterized by an over-current protector and polarity inverter (15), an interference reducing filter (16) connected to a high-frequency inductor (17), which is communicant with an integrated control circuit (18) and also connected to a current rectifier (19), besides a secondary filter (20), equally communicant with the integrated control circuit (18) and also connected to a current controller and charge indicator (21), said component (21) provided with three charge indicator LED-type lamps (22), having three outputs, being output 1 (23), output 2 (24) and common output (25).
